(19) United States
(12) Patent Application Publication
(10) Pub. No.: US 2017/0137962 A1
(43) Pub. Date: May 18, 2017

(54) Fabrication Method for Growing Single Crystal of Multi-Type Compound

(71) Applicant: National Chung-Shan Institute of Science and Technology, Taoyuan (TW)

(72) Inventors: Dai-Liang Ma, Taoyuan (TW); Bang-Ying Yu, Taoyuan (TW); Hsueh-I Chen, Taoyuan (TW); Tsao-Chun Peng, Taoyuan (TW); Bo-Chen Lin, Taoyuan (TW); Zhi-Wei Guo, Taoyuan (TW)

(21) Appl. No.: 14/941,755

(22) Filed: Nov. 16, 2015

(51) Int. Cl. C30B 23/00; H01L 21/02; C30B 29/40; C30B 23/06; C30B 29/36

(52) U.S. Cl. CPC C30B 23/002; C30B 23/06; C30B 29/36; C30B 29/403; H01L 21/02529; H01L 21/0254; H01L 21/02631

(57) ABSTRACT

A fabricating method for growing a single crystal of a multi-type compound comprises steps of: (a) providing a seed crystal at a deposition region; (b) providing a powder material at a high purity source region; and (c) undertaking a vacuum process, a heating process, a growing process, a cooling process to prepare the singe crystal, wherein a heating source is used to move to control a temperature gradient within a gas temperature control region to form a temperature gradient motion so that the temperature gradient presents a variation. By reducing the possibility of other deficiencies being continuously induced in the following crystal growth process owing to the local slime occurring at the rear side of the seed crystal from the void deficiencies at the rear side of the original seed crystal may be excluded, but also the possibility of other multi-type bodies being induced by the above vacancies.

### FIELD OF THE INVENTION

The present invention relates to a fabricating method for a single crystal of a multi-type compound, and particularly to such a method for fabricating a large sized crystal with silicon carbon or nitride by using a physical vapor transport (PVT) method.

### DESCRIPTION OF THE RELATED ART

Recently, the technology and living quality have developed rapidly, and thus various types of 3C high-tech electronic product have progressively been manufactured toward light and compact and multi-functions. Hence, compounds such as SiC and the nitride of the III-group elements, such as GaN, and AlN, have been used as the semiconductor material for various electronic devices. Such semiconductor material has a high physical strength and a high erosion-resistant strength, and also an excellent electronic characteristic, including a radiation hardness, a high punch-through electric field, a wider energy band gap, a high-saturation electronic drift speed, high temperature operability, etc.

The physical vapor transport (PVT) method and the physical vapor deposition (PVD) method are usually employed to grow the crystal of silicon carbon and the nitride of the III group elements, and may be used as a technology for mass chips fabrication. Such crystal growth is mainly achieved by using the PVT where a powder form of SiC and the nitride of the III-group elements are sublimed in a high temperature furnace, where a temperature gradient is used to facilitate a vapor motion of the SiC and the nitride of the III-group element to grow its crystal on a seed crystal.

However, the SiC and the nitride of the II-group elements' crystal growth by using the PVT has the following advantages. Now the SiC case is taken as an example for description. A graphite thermally-conductive layer has some infects running inside the crystal. Stein is the first one finding hexagonal vacancies in the SiC crystal grown by the PVT in 1993, exclaiming this formation is obtained from a planar vaporization at a rear side of the crystal. And nucleation points are located at infects between the seed crystal and another seed crystal. Now referring to FIG. 1, defects of a conventional crystal growth technology is shown therein. In the course of the crystal growth, the hexagonal vacancies are caused to move by the evaporation occurring at a bottom portion of the hexagonal vacancies at the growth stage of the hexagonal vacancies (near the seed crystal) and at a top portion of the hexagonal vacancies (near the growth surface). And the hexagonal vacancies located at the graphite thermally-conductive layer (12) between the seed crystal (13) and a seed crystal seat (11) may result in the hexagonal vacancies, and other sources such as 6H (or 15R) multi-crystalline embedded articles (15), carbon-rich deposition region, thermally-decomposed voids are also caused from the same reason. In literatures or patents, these vacancies may be avoided by coating a uniform photo-resistant layer at the rear side of the seed crystal, where the poor thermally-conductive phenomenon caused by the SiC owing to the voids is blocked and a local sublime takes place at the rear of the seed crystal. However, this may induce more vacancies to present in the course of the crystal growth.

In the prior art, there has been some patents such as EP2664695A1, U.S. Pat. No. 7,371,281B2, U.S. Pat. No. 7,695,565B2, U.S. Pat. No. 6,336,971 set forth to overcome the above demerits to promote a growth speed of the Single crystal SiC and polycrystal. These overcoming technologies include the following technologies: 1. Improvement of material and structure of the high temperature furnace. 2. Control over supply of the raw material. 3. Variation of Components or proportion of the raw material. 4. Improvement of the gas flow control device. By means of these technologies the growth speed at the surface of the seed crystal may be promoted, and seed crystal quality may be improved and the growth speed of the crystal may be enhanced.

Therefore, there is a need in the field to develop a PVT for SiC and nitride's crystal growth, to overcome the demerits, such as top of the vacancies, hexagonal vacancies, polycrystalline embedded article, carbon-rich deposition region, thermally-decomposed voids. In this manner, a single crystal equipping with simultaneous high efficiency and quality.

### SUMMARY OF THE INVENTION

It is, therefore, an object of the present invention to provide a fabricating method for growing a single crystal of a multi-type compound, in which the multi-type compound may be SiC or a nitride, such as the nitride of the III-group elements. The fabricating method is integrated with a vacuum process, a heating process, a crystal growth process, and a cooling process, in which a heating source is moved to prepare and manufacture a large sized single crystalline material under the consideration of environmental protection and safety.

According to the present invention, the fabricating method for growing a single crystal of a multi-type compound comprises steps of: (a) providing a seed crystal at a deposition region; (b) providing a powder material at a high purity source region; and (c) undertaking a vacuum process, a heating process, a growing process, a cooling process to prepare the singe crystal, wherein a heating source is used to move to control a temperature gradient within a gas temperature control region to form a temperature gradient motion so that the temperature gradient presents a variation.

In step (c), the heating source may be a heating coil, and particularly an induced heating coil. In the present invention, the heating coil may be controlled on its placement to enlarge an axial temperature difference (a vertical direction of a high temperature furnace or a direction from the deposition region to the high purity source region), and promote a degree of supersaturation and control a pressure within the high temperature furnace, so that the SiC or the nitride is formed with its 2-dimensional nucleation with its gaseous molecule on the seed crystal. As such, a high density growth stage is grown and Single crystal SiC is rapidly deposited, so that the crystal growth speed of the SiC or the nitride at the surface of the seed crystal is larger than a decomposition speed of the SiC or the nitride under a local sublime at the rear side of the seed crystal. The heating coil may have a motion speed range of 30 mm/min to 5E-4 mm/min and a motion direction parallel with the axial direction of the high temperature furnace (the vertical direction or the direction from the deposition region to the high purity source region), which may be upward or downward.

By means of the motion of the heating coil, the gas temperature gradient control region has a temperature gradient range of 3-12° C./cm, at the same time the deposition region and the high purity source region has a temperature difference ranging from 90-350° C./cm.

A SiC or nitride single wafer may be used as the seed crystal, the seed crystal being selected from a group consisting of 3C, 4H, 6H, 2H, a 15R, and a combination thereof, and the above preparation and manufacturing method for growing the single crystal having a corresponding crystalline state may be used to prepare and manufacture a single crystal having a high density stage larger than 100/cm by using the seed crystal.

The above summary and the following description and accompanying drawings are taken for further explanation of the fashion, means and effectiveness of the present invention for its object. Other objects and advantages of the present invention will be described in the following description and drawings.

### BRIEF DESCRIPTIONS OF THE DRAWINGS

The present invention will be better understood from the following detailed descriptions of the preferred embodiments according to the present invention, taken in conjunction with the accompanying drawings, in which:

FIG. 1 is a schematic diagram of defects of a crystal growth by using the prior art technology;

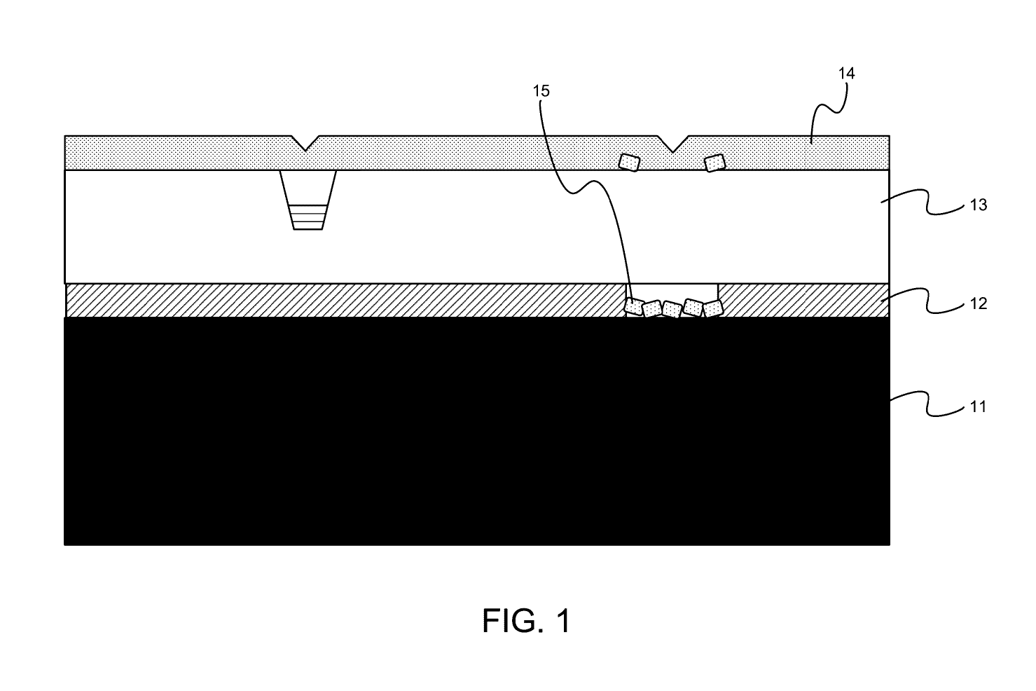

FIG. 2 is a schematic diagram of a high system furnace system for preparing and manufacturing a single crystal according to the present invention;

FIG. 3 is a flowchart for illustrating a fabricating method for a single crystal of a multi-type compound according to the present invention;

FIG. 4 is a schematic diagram of a temperature-pressure control when a physical vapor deposition method according to an embodiment of the present invention;

FIG. 5(a) is a single crystal SiC's slice as a comparative example according to the present invention; and

FIG. 5(b) is a single crystal SiC's slice as an embodiment according to the present invention.

### DESCRIPTION OF THE PREFERRED EMBODIMENTS

The present invention will be apparent from the following detailed description, which proceeds with reference to the accompanying drawings, wherein the same references relate to the same elements.

It is a main object to provide a fabricating method for a single crystal, such as SiC crystal and nitride crystal, having a high growth speed, where a heating coil (heating source) is controlled in its placement to promote a system temperature gradient and a supersaturation of a high temperature furnace and a SiC material's use speed, to promote a deposition speed of the SiC at a crystal growth surface of a seed crystal, so as to improve the quality of a seed crystal and promote the growth speed of the crystal. By using this technology, a large sized single crystal may be manufactured in an easier manufacturing fashion. In essence, when an atom is bonded at an interface, a bonding energy intension is in an inversely proportional relationship with neighboring atoms with a consideration of an interaction between the atom and the neighboring atoms. The larger the energy released from the crystal growth, the more benefitted the atom is bonded at this site. Hence, when only the interface is smooth, a stage may not be formed with an aid of an activation energy, and 2 dimensional nucleation is required to be continuously formed to form the stage. The stage is relied upon to maintain the growth. Therefore, the preparation of a single crystal surface having a high density stage is critical to the promotion of the single crystal' growth speed.

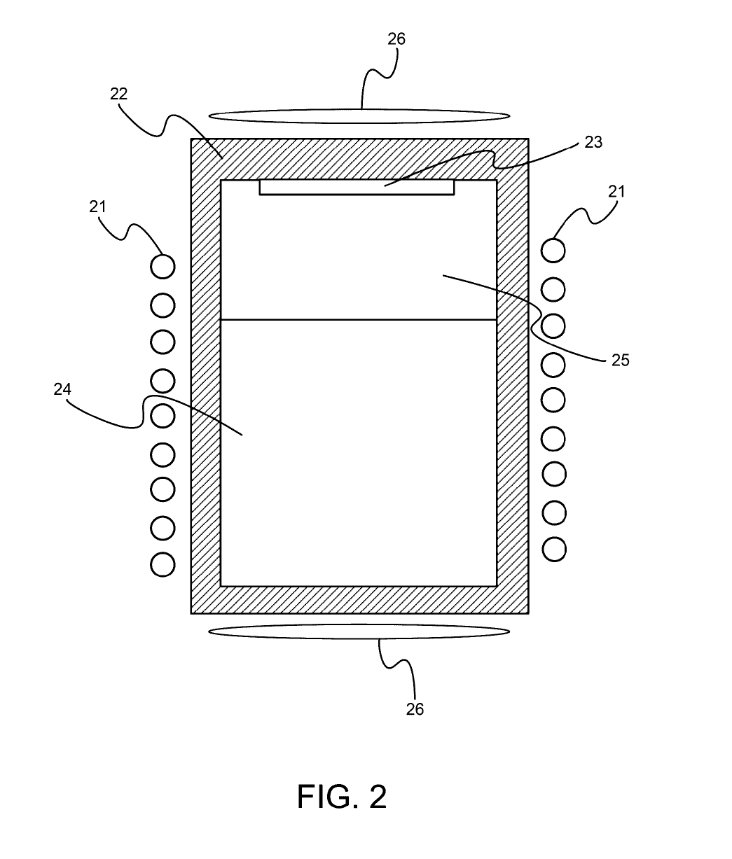

Referring to FIG. 2, a schematic diagram of the high system furnace system for preparing and manufacturing the single crystal according to the present invention is shown therein. As shown, the high temperature furnace includes a movable heating source (21), a high temperature cavity (22), a deposition region (23), a high purity source region (24), a gaseous temperature gradient control region (25). The movable heating source (21) may be a heating coil, and particularly an induced heating coil. Inside the deposition region (23), a holder may be arranged to fix the seed crystal. The whole deposition region (23) is located at a position above the high temperature furnace cavity (22), and the position is a cool end having a relatively lower temperature within the high temperature furnace cavity (22) during the crystal growth process. On the other hand, the high purity source region (24) is located at another position below the deposition region (23) to receive some material source (such as a high purity SiC or a nitride powder material), and the position is a hot end having a relatively higher temperature within the high temperature furnace cavity (22) during the crystal growth process. Based on this arrangement the raw material (powder material) may be sublimed to gaseous molecules from its original solid form, to control the temperature, heat field, atmosphere, and pressure within the heating device, so that the molecules such as the SiC's transported to on the seed crystal at the deposition region (23). By controlling the respective temperature of the cool end and the hot end, a temperature difference along the high temperature furnace system and a varied temperature gradient within the gaseous temperature gradient control region (25) and the pressure within the pressure within the system are controlled, so that the gaseous molecules of the SiC or the nitride deposit rapidly on the seed crystal to form a deposited single crystal. In this manner, the crystal growth occurring on the seed crystal's surface is larger in growth speed than a decomposition speed of the locally sublimed SiC occurring at a rear side of the seed crystal.

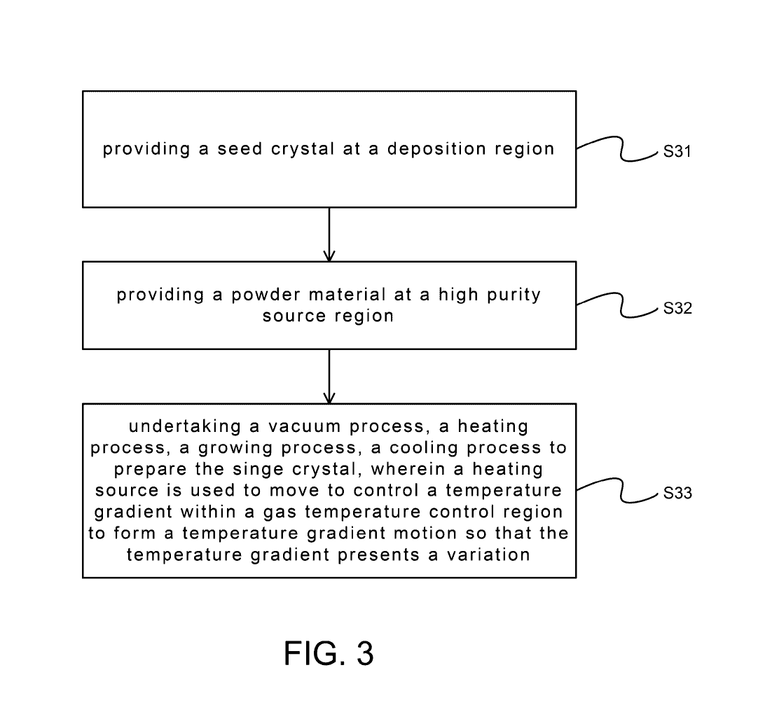

Referring to FIG. 3, a fabricating method for growing a single crystal of a multi-type compound according to the present invention is shown therein, in which the multi-type compound may be SiC or nitride. As shown, the method comprises following steps. (a) A seed crystal at a deposition region is provided (S31). (b) A powder material at a high purity source region (S32). (c) Undertaking a vacuum process, a heating process, a growing process, a cooling process to prepare the singe crystal (S33). In the method, a heating source is used to move to control a temperature gradient within a gas temperature control region to form a temperature gradient motion so that the temperature gradient presents a variation.

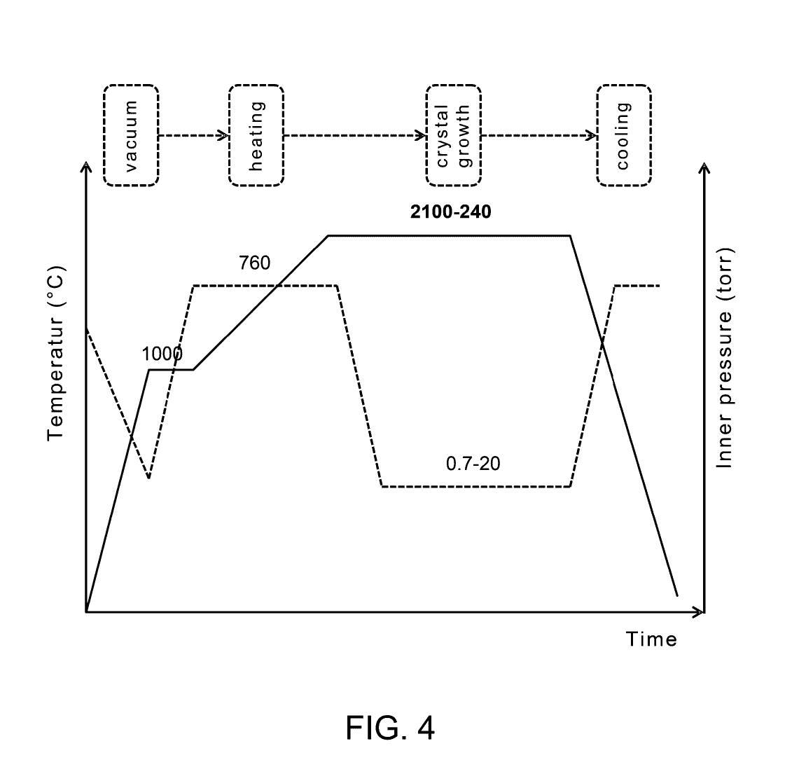

Referring to FIG. 4, a schematic diagram of a temperature-pressure control when a physical vapor deposition (PVT) method according to an embodiment of the present invention. As shown, the PVT method is relied upon to prepare and manufacture a 4H-Single crystal SiC in the embodiment. The growth process takes place on the high temperature furnace. The SiC powder material having a high purity of above 99% an average particle degree of 1 to 30 mm is used as a commence material. A crystal growth temperature is designated as about 2,100 to 2,250° C. Ar is selected as a carrier gas in the system. A pressure of about 0.7 to 5 torr is designated for the system crystal growth. A growth time is 30 hr. is designated. The seed crystal is a Single crystal SiC wafer having a thickness of about 350 μm. In the vacuum process, the 4H-SiC seed crystal is fixed by a holder and then vacuumed, to remove air and other impurities within the high temperature furnace system. In the heating process, an inert gas Ar (or N₂) and some auxiliary gases hydrogen, methane, ammonia are introduced. The heating coil is heated to about 2,100 to 2,250° C. within the whole system. In the crystal growth process, the crystal growth's pressure is 0.7 to 5 torr. The heating coil is lowered for its position by a speed about 1 mm/min with a lowered distance of 6 cm. The coil is displaced by using a time of 1 hr. Since the heating coil takes six times of motion, the temperature gradient within the gas temperature gradient control region presents a variation of the temperature gradient continuously, and the temperature gradient is enabled to become larger. In the crystal growth process, an upper portion (the deposition region) of the high temperature furnace and a lower portion (high purity source region) of the high temperature furnace, having a temperature up to 3-12° C./cm. In the cooling process, the finished single crystal may be subject to an annealing process. In a comparative example, the above same conditions are adopted except that the shift and position of the heating coil are not adjusted and controlled, the upper portion (deposition region) and the lower region (high purity source region) have a temperature difference of 40 to 80° C. and a temperature gradient of 1.3-2.7° C./cm.

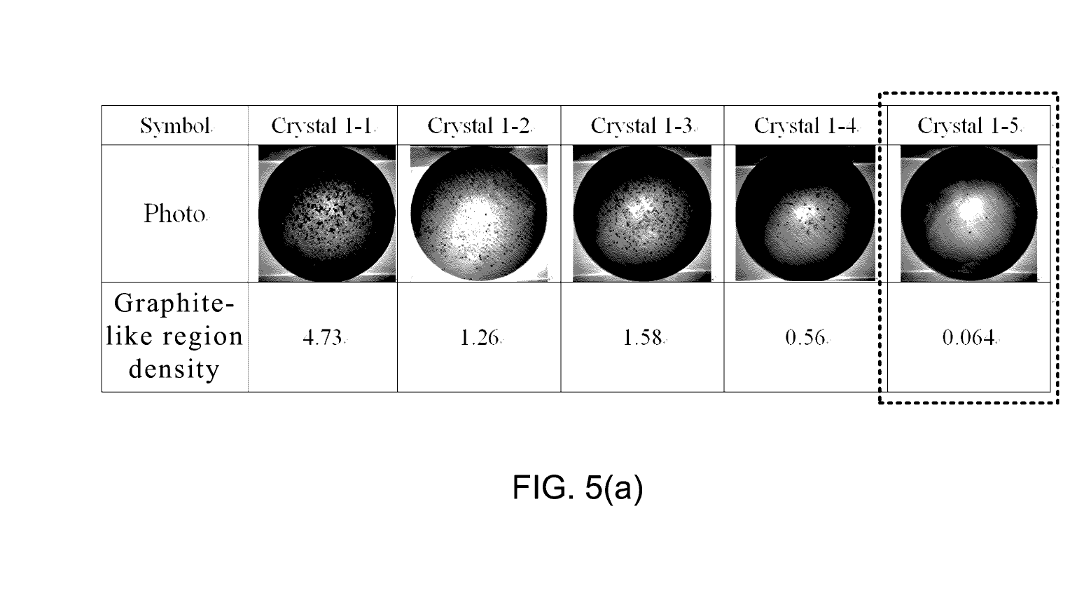

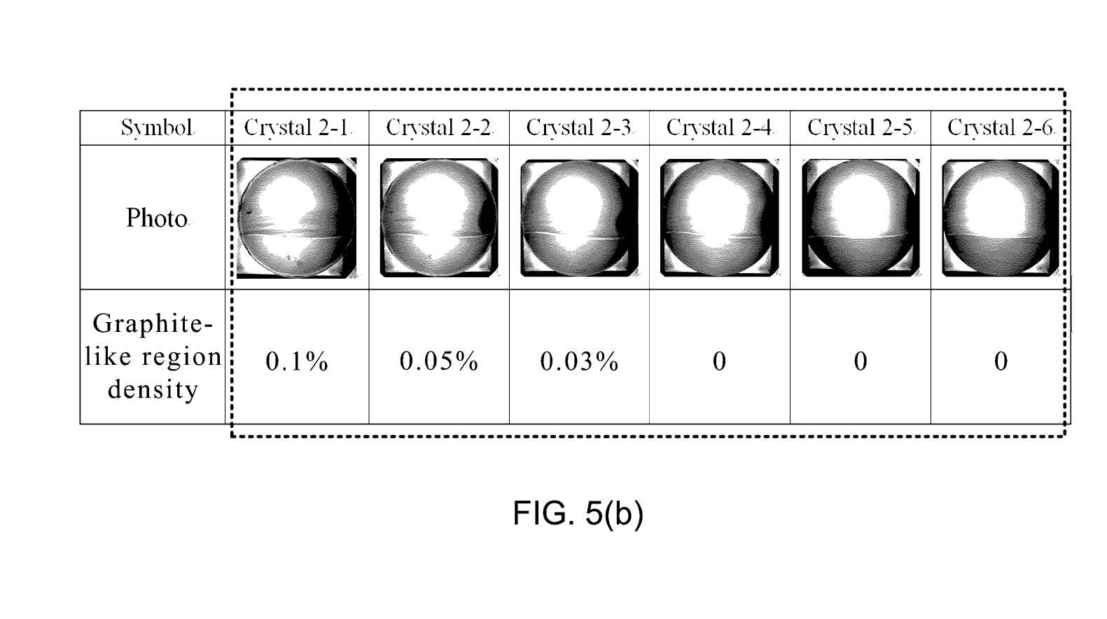

Referring to FIG. 5(a) and FIG. 5(b), a single crystal SiC's slice as a comparative example according to the present invention and a single crystal SiC slice as an embodiment according to the present invention are shown therein, respectively. As shown, the quality within the single crystal may be ascertained for the embodiment's and comparative example's single crystal. It is found that only one slice from five of the comparative's grown single crystal SiC may be used to be undertaken with following processes (such as the slice framed with red). On the other hand, the SiC crystal manufactured in the embodiment have all six slices are qualified into the following process. Therefore, the quality and the qualified number are significantly promoted, and may effectively reduce a ratio of the seed crystal's deficiencies extending continuously into the crystal among all, showing an evidence that the present invention may effectively promote the quality and a yield of the single crystal SiC.

The present invention is a fabricating method for a single crystal of a multi-type compound. The effectiveness dwells in that the growth speed is high up to 300 600 μm/hr. At the same time, the surface of the single crystal has a growth stage and the finished crystal may have a diameter of up to 2 to 6 inches. In the embodiment, the 350 μm single crystal SiC wafer may cultivate a crystal after two to three hours by using the PVT method with a thickness of 0.8 to 1.5 mm and a high density growth stage larger than 100/cm at its surface. The seed crystal is then taken as a thick seed crystal for the following SiC seed crystal's growth. Not only the extended hexagonal vacancies, carbon group, silicon drip deposition caused from the void deficiencies at the rear side of the original seed crystal may be excluded, but also the possibility of other multi-type bodies being induced by the above vacancies. This may promote the single crystal SiC's growth quality and the powder material may be significantly used, well lending to its mass production.

From all these views, the present invention may be deemed as being more effective, practical, useful for the consumer's demand, and thus may meet with the requirements for a patent.

The above described is merely examples and preferred embodiments of the present invention, and not exemplified to intend to limit the present invention. Any modifications and changes without departing from the scope of the spirit of the present invention are deemed as within the scope of the present invention. The scope of the present invention is to be interpreted with the scope as defined in the claims.

What is claimed is:

1. A fabricating method for growing a single crystal of a multi-type compound, comprising steps of:
(a) providing a seed crystal at a deposition region;
(b) providing a powder material at a high purity source region; and
(c) undertaking a vacuum process, a heating process, a growing process, a cooling process to prepare the singe crystal,
(d) wherein a heating source is used to move to control a temperature gradient within a gas temperature control region to form a temperature gradient motion so that the temperature gradient presents a variation.

2. The method as claimed in claim 1, wherein the powder material is a silicon carbon powder material or a nitride power material.

3. The method as claimed in claim 1, wherein the heating source is a heating coil.

4. The method as claimed in claim 1, wherein the heating coil has a moving direction of a vertical direction.

5. The method as claimed in claim 1, wherein the heating coil has a motion speed range of 30 mm/min to 5E-4 mm/min.

6. The method as claimed in claim 1, wherein the gas temperature gradient control region has a temperature gradient range of 3-12° C./cm.

7. The method as claimed in claim 1, wherein the deposition region and the high purity source region has a temperature difference ranging from 90-350° C./cm.

8. The method as claimed in claim 1, wherein the seed crystal is a single crystal wafer having a thickness of at least 350 μm and a diameter of 2 inches to 6 inches and above, and used to grow the single crystal having a corresponding or larger size.

9. The method as claimed in claim 1, wherein the seed crystal is selected from a group consisting of 3C, 4H, 6H, 2H, a 15R, and a combination thereof, and used for growing the single crystal having a corresponding crystalline state.
